(19) United States
(12) Patent Application Publication
(10) Pub. No.: US 2017/0207194 A1
(43) Pub. Date: Jul. 20, 2017

(54) CHIP PACKAGE AND METHOD FOR FORMING THE SAME

(71) Applicant: XINTEC INC., Taoyuan City (TW)

(72) Inventors: Hsing-Lung SHEN, Hsinchu City (TW); Jiun-Yen LAI, Taipei City (TW); Yu-Ting HUANG, Taoyuan City (TW); Tsung-Cheng CHAN, Nantou City (TW); Jan-Lian LIAO, Taoyuan City (TW); Hung-Chang CHEN, New Taipei City (TW); Ming-Chieh HUANG, Kaohsiung City (TW); Hsi-Chien LIN, Zhubei City (TW)

(21) Appl. No.: 15/409,511

(22) Filed: Jan. 18, 2017

Related U.S. Application Data
(60) Provisional application No. 62/280,624, filed on Jan. 19, 2016.
(60) Provisional application No. 62/281,655, filed on Jan. 21, 2016.

(51) Int. Cl. H01L 25/065; H01L 23/29; H01L 21/56; H01L 25/00; H01L 23/31; H01L 23/00

(52) U.S. Cl. CPC H01L 25/0652; H01L 23/3135; H01L 23/3128; H01L 24/06; H01L 23/3171; H01L 24/13; H01L 21/563; H01L 25/50; H01L 23/295; H01L 24/03; H01L 2224/02373

(57) ABSTRACT

A chip package is provided. The chip package includes a first chip including a carrier substrate and a device substrate thereon. A second chip is mounted on the device substrate. A portion of the device substrate extends outward from the edge of the second chip, so as to be exposed from the second chip. A conductive pad is between the device substrate and the second chip. A polymer protective layer conformally covers the second chip, the exposed portion of the device substrate, and the edge of the carrier substrate. A redistribution layer is disposed on the polymer protective layer and extends into a first opening that passes through the polymer protective layer and the second chip and exposes the conductive pad, so as to be electrically connected to the conductive pad.

### CROSS REFERENCE TO RELATED APPLICATIONS

This application claims the benefit of U.S. Provisional Application No. 62/280,624 filed on Jan. 19, 2016 and U.S. Provisional Application No. 62/281,655 filed on Jan. 21, 2016, the entirety of which is incorporated by reference herein.

### BACKGROUND OF THE INVENTION

Field of the Invention

The invention relates to chip package technology, and in particular to a chip package and methods for forming the same.

Description of the Related Art

As demand increases for electronic or optoelectronic products such as digital cameras, camera phones, bar code readers, and monitors, and as product trends require miniaturization of semiconductor chip sizes and increased and more complex functionality of semiconductor chips, the semiconductor technology used in such products must be developed rapidly.

Due to performance demands, most semiconductor chips are typically placed in a sealed package for operational stability. Therefore, the chip package process is an important process for the fabrication of electronic products. The chip package not only protects the chip therein from ambient contamination, but also provides electrical connections between the interior electronic devices and exterior circuits. However, with the complicated functionality of the electronic or optoelectronics products, the difficulty of forming the packages may be increased and/or the reliability of such packages may be reduced.

FIG. 1 is a cross-sectional view of a portion of a chip package 10. The chip package 10 includes a micro-electromechanical systems (MEMS) chip. The MEMS chip typically includes a carrier substrate 100 and an overlying MEMS device substrate 200. Moreover, the chip package 10 further includes a control device chip 300, such as an application-specific integrated circuit (ASIC) chip. The control device chip 300 is mounted on the MEMS chip and is electrically connected to conductive structures 200a of the MEMS device substrate 200.

As shown in FIG. 1, the edge portion of the MEMS device substrate 200 is uncovered by the control device chip 300. Namely, the edge portion of the MEMS device substrate 200 extends outward from the edge 301 of the control device chip 300. However, in the fabrication of the chip package 10, the edge portion of the MEMS device substrate 200 that extends outward (i.e., the portion that is uncovered by the control device chip 300) may easily become damaged or removed during the etching process that is performed on the control device chip 300, such that a recess between the control device chip 300 and the carrier substrate 100 is formed at the edge of the MEMS device substrate 200. As a result, in the subsequent fabrication of the redistribution layers (RDLs), the RDL that is adjacent to the recess can be broken easily. Moreover, the edge of the control device chip 300 can also break during a thinning process (e.g., a polishing process) on the carrier substrate 100.

Accordingly, there exists a need in the art for development of a chip package and methods for forming the same capable of eliminating or mitigating the aforementioned problems.

### BRIEF SUMMARY OF THE INVENTION

An embodiment of the invention provides a chip package which includes a first chip including a carrier substrate and a device substrate that is disposed on the carrier substrate. A second chip is mounted on the device substrate, in which a portion of the device substrate extends outward from an edge of the second chip, so as to be exposed from the second chip. A conductive pad is disposed between the device substrate and the second chip. A polymer protective layer conformally covers the edge of the second chip, an edge of the exposed portion of the device substrate, and an edge of the carrier substrate. A redistribution layer is disposed on the polymer protective layer and extends into a first opening that passes through the polymer protective layer and the second chip and exposes the conductive pad, so as to be electrically connected to the conductive pad.

Another embodiment of the invention provides a method for forming a chip package which includes providing a first chip that includes a carrier substrate and a device substrate disposed on the carrier substrate. A second chip is mounted on the device substrate, in which a portion of the device substrate extends outward from an edge of the second chip, so as to be exposed from the second chip. A polymer protective layer is formed to conformally cover the edge of the second chip, an edge of the exposed portion of the device substrate, and an edge of the carrier substrate. A first opening passing through the polymer protective layer and the second chip is formed to expose a conductive pad between the device substrate and the second chip. A redistribution layer is formed on the polymer protective layer and extends into the first opening, so as to be electrically connected to the conductive pad.

### BRIEF DESCRIPTION OF THE DRAWINGS

The present invention can be more fully understood by reading the subsequent detailed description and examples with references made to the accompanying drawings, wherein:

FIG. 1 is a cross-sectional view of a chip package.

FIGS. 2A to 2H are cross-sectional views of an exemplary embodiment of various intermediate stages for forming a chip package according to the invention.

FIGS. 3A to 3H are cross-sectional views of an exemplary embodiment of various intermediate stages for forming a chip package according to the invention.

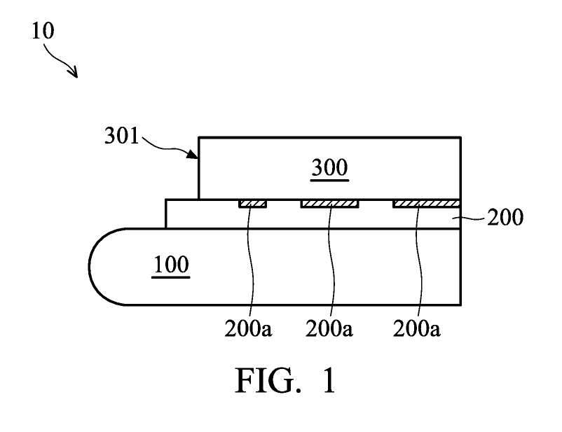

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Furthermore, when a first material layer is referred to as being on or overlying a second material layer, the first material layer may be in direct contact with the second material layer, or spaced apart from the second material layer by one or more material layers.

A chip package according to an embodiment of the present invention may be used to package micro-electromechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electromechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multilayer integrated circuit devices by stacking a plurality of wafers having integrated circuits.

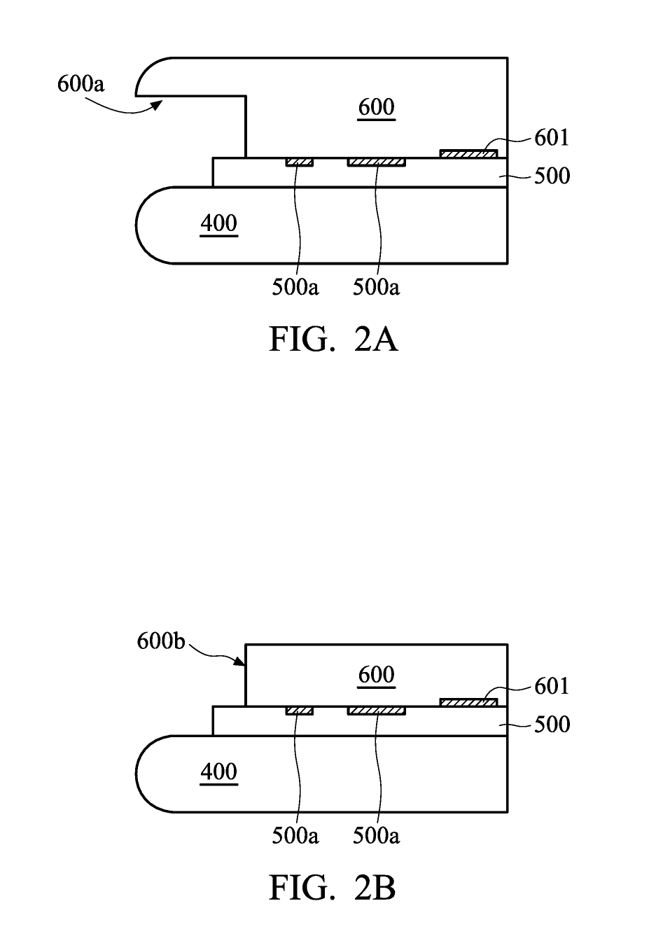

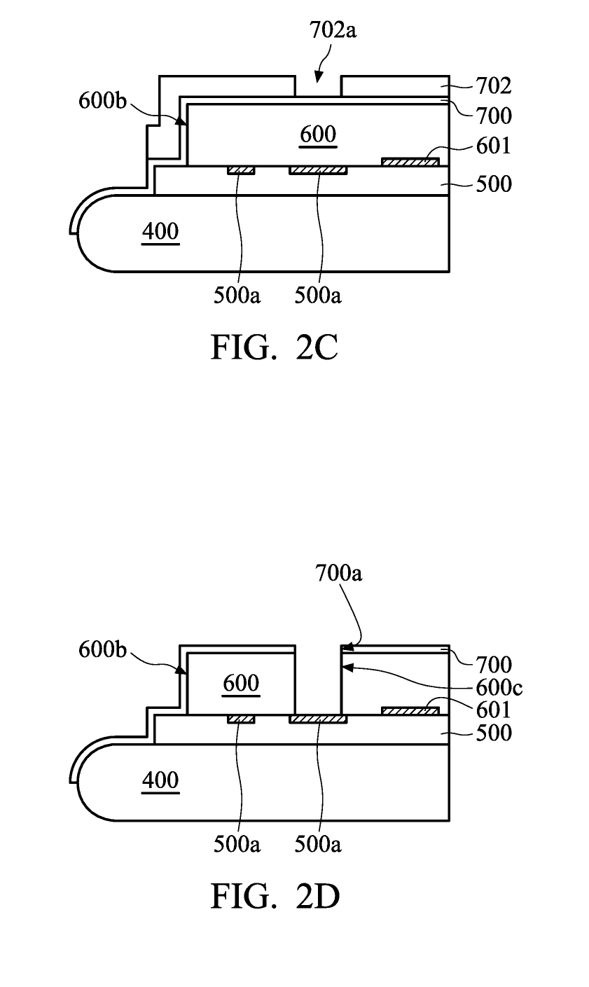

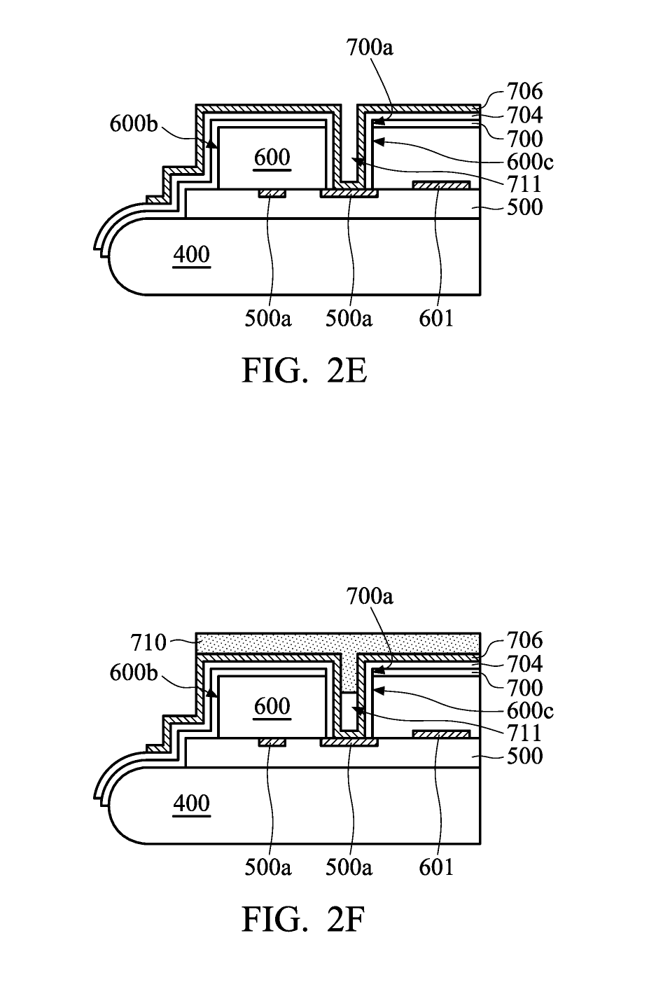

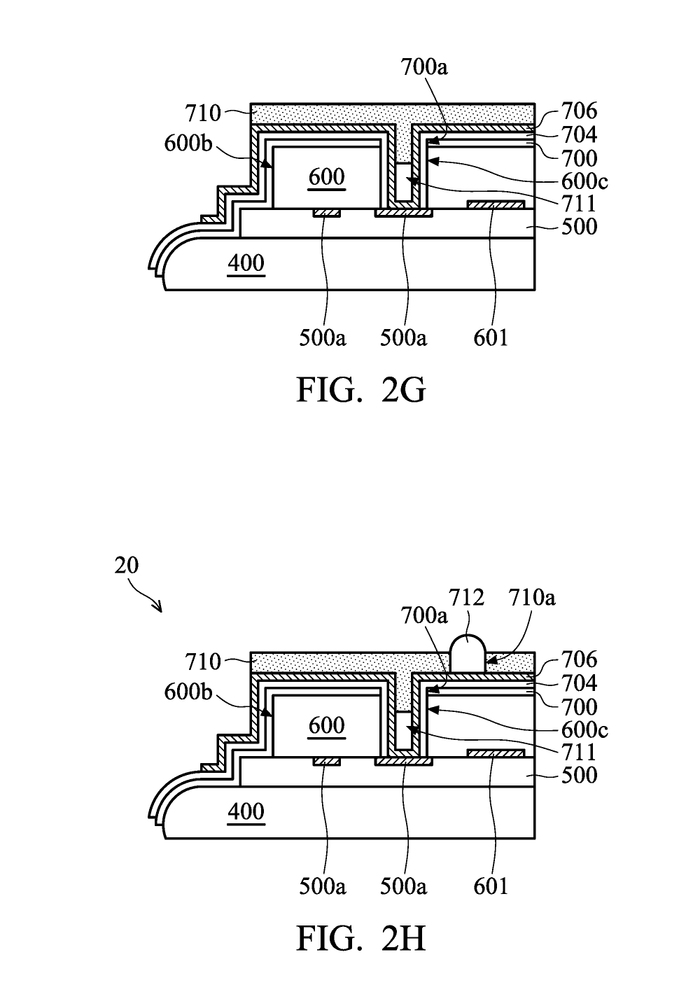

Refer to FIG. 2H, in which a cross-sectional view of an exemplary embodiment of a chip package 20 according to the invention is illustrated. In the embodiment, the chip package 20 includes a first chip that includes a carrier substrate 400 and a device substrate 500 disposed thereon. Note that the term “chip” throughout the present disclosure may represent “wafer” before a dicing process performed on the package. In the embodiment, the device substrate 500 includes a silicon substrate or another semiconductor substrate. Moreover, in one embodiment, the device substrate 500 includes a MEMS device, and therefore the device substrate 500 is also referred to as a MEMS device substrate.

The device substrate 500 typically includes a body and a metallization layer formed on the body. Herein, in order to simplify the diagram, only a flat layer is depicted. In one embodiment, the device substrate 500 includes a silicon body or another semiconductor body. Moreover, the metallization layer of the device substrate 500 includes a dielectric material layer and an interconnect structure (not shown) disposed in the dielectric material layer. Furthermore, the metallization layer of the device substrate 500 has a conductive structure 500a therein and the conductive structure 500a includes one or more conductive pads and one or more conductive wires. The conductive pad and the conductive wire in the metallization layer are typically formed of an uppermost metal layer and exposed from a surface (e.g., an upper surface of the metallization layer) of the device substrate 500. In one embodiment, the interconnect structure in the metallization layer is electrically connected to the conductive structure 500a.

In the embodiment, the chip package 20 further includes a second chip 600 that is mounted on the device substrate 500. In one embodiment, the second chip 600 includes a control device chip, such as an ASIC chip. In this case, the second chip 600 is also referred to as an ASIC chip. The second chip 600 has at least one conductive pad 601 between the device substrate 500 and the second chip 600. The conductive pad 601 may be electrically connected to the conductive structure 500a of the device substrate 500. Moreover, the second chip 600 has at least one opening 600c exposing a corresponding conductive pad of the conductive structure 500a that is disposed between the device substrate 500 and the second chip 600. In the embodiment, since the planar size of the second chip 600 is smaller than that of the device substrate 500, a portion of the device substrate 500 extends outward from the edge 600b of the second chip 600, so as to be exposed from the second chip 600 (i.e., uncovered by the second chip 600).

In the embodiment, the chip package 20 further includes a polymer protective layer 700 that conformally covers the upper surface and sidewalls of the second chip 600, the exposed portion of the device substrate 500, and the edge of the carrier substrate 400. Moreover, the polymer protective layer 700 has an opening 700a that substantially aligns to the opening 600c of the second chip 600, so as to form a combined opening passing through the polymer protective layer 700 and the second chip 600 and exposing the conductive pad on the surface of the device substrate 500. In one embodiment, the polymer protective layer 700 includes a photo-sensitive material, such as a photoresist material. In some embodiments, the polymer protective layer 700 includes an epoxy or another suitable organic polymer material (such as polyimide, butylcyclobutene (BCB), parylene, polynaphthalenes, fluorocarbons, or acrylates).

In the embodiment, the chip package 20 further includes a dielectric layer 704 that is disposed on the polymer protective layer 700 and extends on the sidewalls of the opening 700a of the polymer protective layer 700 and the opening 600c of the second chip 600. In one embodiment, the dielectric layer 704 includes an inorganic material (such as silicon oxide, silicon nitride, silicon oxynitride, metal oxide, or a combination thereof). In some embodiments, the dielectric layer 704 includes an organic polymer material with spacers therein. In these cases, the organic polymer material may be epoxy and the spacers may be silica particles. The epoxy enables the dielectric layer 704 to have fluidity prior to a curing process, and the silica particles lower the coefficient of thermal expansion (CTE) of the dielectric layer 704, so that the CTE of the dielectric layer 704 is approximately the same as that of the second chip 600, thereby avoiding the warping deformation caused by thermal stress.

In the embodiment, the chip package 20 further includes a redistribution layer 706 that is disposed on the dielectric layer 704 and conformally extends on the sidewalls and the bottom of the opening 600c of the second chip 600 through the opening 700a of the polymer protective layer 700, thereby electrically connecting the conductive pad at the bottom of the opening 600c. The redistribution layer 706 is electrically isolated from the second chip 600 via the dielectric layer 704 between the redistribution layer 706 and the polymer protective layer 700. Therefore, the redistribution layer 706 in the openings 700a and 600c is also referred to as a through substrate via. In one embodiment, the redistribution layer 706 includes copper, aluminum, gold, platinum, nickel, tin, a combination thereof, a conductive polymer material, a conductive ceramic material (e.g., indium tin oxide or indium zinc oxide), or another suitable conductive material.

In the embodiment, the chip package 20 further includes a passivation layer 710 and at least one conductive structure 712. The passivation layer 710 is disposed on the redistribution layer 706 and partially fills the opening 600c of the second chip 600, so that a cavity 711 is formed between the conductive pad and the passivation layer 710. Moreover, the passivation layer 710 has at least one opening 710a that exposes a portion of the redistribution layer 706. The cavity 711 can serve as a buffer between the passivation layer 710 and the redistribution layer 706 while performing the heat treatment in the subsequent process steps. As a result, unwanted stress due to the CTE mismatch between the passivation layer 710 and the redistribution layer 706 can be reduced. Moreover, the redistribution layer 706 can be prevented from being excessively pulled by the passivation layer 710 due to rapid changes in external temperature and pressure, thereby preventing delamination or disconnection of the redistribution layer 706 near the conductive pad structure.

In one embodiment, the passivation layer 710 includes an epoxy, a solder mask, an inorganic material (e.g., silicon oxide, silicon nitride, silicon oxynitride, metal oxide, or a combination thereof), an organic polymer material (e.g., polyimide, BCB, parylene, polynaphthalenes, fluorocarbons, acrylates), a photoresist material, or another suitable insulating material.

The conductive structure 712 is disposed in the opening 710a of the passivation layer 710 and is electrically connected to the exposed portion of the redistribution layer 706. In one embodiment, the conductive structure 712 includes a metal bump (e.g., metal bonding ball or a metal post). In this case, the conductive structure 712 may include tin, lead, copper, gold, nickel, or a combination thereof, or another suitable conductive material.

Refer to FIGS. 2A to 2H, which illustrate cross-sectional views of an exemplary embodiment of various intermediate stages for forming a chip package 20 according to the invention. As shown in FIG. 2A, a first chip and a second chip 600. In the embodiment, the first chip includes a carrier substrate 400 and a device substrate 500 that is disposed on the carrier substrate 400. In the embodiment, the carrier substrate 400 includes a silicon substrate or a semiconductor substrate. Moreover, the device substrate 500 may include a MEMS device therein, and therefore the device substrate 500 is also referred to as a MEMS device substrate. As previously mentioned, the device substrate 500 typically includes a body and a metallization layer formed on the body. Moreover, the metallization layer of the device substrate 500 has a conductive structure 500a therein and the conductive structure 500a includes one or more conductive pads and one or more conductive wires. The second chip 600 includes a control device chip, such as an ASIC chip. In this case, the second chip 600 is also referred to as an ASIC chip. The second chip 600 has at least one conductive pad 601 that may be electrically connected to the conductive structure 500a of the device substrate 500. Moreover, the second chip 600 has at least one opening 600a near the edge of the second chip 600, so that the edge thickness of the second chip 600 is less than that the central thickness of the second chip 600. Next, the second chip 600 is mounted on the device substrate 500, such that the top of the opening 600a is adjacent to the edge of the device substrate 500.

Refer to FIG. 2B, a polishing process (e.g., a chemical mechanical polishing process) is performed on the second chip 600 to remove the portion of the second chip 600 below the opening 600a. In some embodiments, an etching process (e.g., a dry etching process) is performed after performing the polishing process to further reduce the thickness of the second chip 600. As a result, the remaining second chip 600 has an edge 600b formed of the sidewall of the opening 600a. Moreover, the remaining second chip 600 has a planar size smaller than that of the device substrate 500, so that a portion of the device substrate 500 extends outward from the edge 600b of the second chip, so as to be exposed from the second chip 600.

Refer to FIG. 2C, a polymer protective layer 700 is formed to conformally cover the upper surface (i.e., the polished/etched surface) and the sidewall (i.e., the edge 600b) of the second chip 600, the upper surface and the sidewall of the exposed portion of the device substrate 500, and the edge of the carrier substrate 400. In one embodiment, the polymer protective layer 700 includes an epoxy or another suitable organic polymer material (e.g., polyimide, BCB, parylene, polynaphthalenes, fluorocarbons, or acrylates). Thereafter, a masking pattern layer 702 is formed on the polymer protective layer 700, such as a photoresist pattern layer, above the device substrate 500 and the second chip 600. The masking pattern layer 702 has at least one opening 702a exposing a portion of the polymer protective layer 700 and corresponding to a conductive pad of the device substrate 500.

Refer to FIG. 2D, the polymer protective layer 700 and the underlying second chip 600 are successively patterned using the masking pattern layer 702 as an etch mask, so as to respectively form openings 700a and 600c in the polymer protective layer 700 and the underlying second chip 600, thereby exposing the conductive pad on the device substrate 500. Next, the masking pattern layer 702 is removed. In some embodiments, the polymer protective layer 700 includes a light-sensitive material, such as a photoresist material. As a result, there is no need to use the masking pattern layer 702 as an etch mask, and the opening 700a can be formed by a lithography process. In these cases, the second chip 600 is patterned using the polymer protective layer 700 having the opening 700a as an etch mask, so that the opening 600c is formed in the second chip 600, so as to expose the conductive pad on the device substrate 500.

Refer to FIG. 2E, a dielectric layer 704 is conformally formed on the polymer protective layer 700. In the embodiment, the dielectric layer 704 extends on the sidewall and bottom of the opening 700a of the polymer protective layer 700 and the sidewall and bottom of the opening 600c of the second chip 600. In one embodiment, the dielectric layer 704 includes an inorganic material (such as silicon oxide, silicon nitride, silicon oxynitride, metal oxide, or a combination thereof). For example, the dielectric layer 704 may include silicon oxide that is formed by a chemical vapor deposition process. In some embodiments, the dielectric layer 704 includes an organic polymer material (such as epoxy). In these cases, the dielectric layer 704 is formed by a spin coating process. Thereafter, an etching process is performed on the dielectric layer 704 to remove the portion of the dielectric layer 704 at the bottom of the opening 600c, so as to expose the conductive pad on the device substrate 500.

Next, a redistribution layer 706 is conformally formed on the dielectric layer 704. In the embodiment, the redistribution layer 706 conformally extends on the sidewall and the bottom of the opening 600c of the second chip 600 through the opening 700a of the polymer protective layer 700, so as to be electrically connected to the conductive pad at the bottom of the opening 600c. The redistribution layer 706 is electrically isolated from the second chip 600 via the dielectric layer 704 between the redistribution layer 706 and the polymer protective layer 700. In one embodiment, the redistribution layer 706 includes copper, aluminum, gold, platinum, nickel, tin, a combination thereof, a conductive polymer material, a conductive ceramic material (e.g., indium tin oxide or indium zinc oxide), or another suitable conductive material.

Refer to FIG. 2F, a passivation layer 710 is formed on the redistribution layer 706 and partially fills the opening 600c of the second chip 600, so that a cavity 711 is formed between the conductive pad and the passivation layer 710. In one embodiment, the passivation layer 710 includes an epoxy, a solder mask, an inorganic material, an organic polymer material, a photoresist material, or another suitable insulating material.

Refer to FIG. 2G, a polishing process (e.g., a chemical mechanical polishing process) is performed on the carrier substrate 400 to thin the thickness of the carrier substrate 400.

Refer to FIG. 2H, the passivation layer 710 is patterned by lithography and etching processes to form at least one opening 710a that exposes a portion of the redistribution layer 706. In some embodiments, the passivation layer 710 includes a photoresist material. As a result, the opening 710a can be formed by a lithography process when the passivation layer 710 is formed. Thereafter, a conductive structure 712 is formed in the opening 710a of the passivation layer 710, so as to be electrically connected to the exposed portion of the redistribution layer 706. In one embodiment, the conductive structure 712 includes a metal bump (e.g., metal bonding ball or a metal post). Thereafter, a dicing process may be performed along the scribe lines (not shown) to complete the fabrication of the chip package 20.

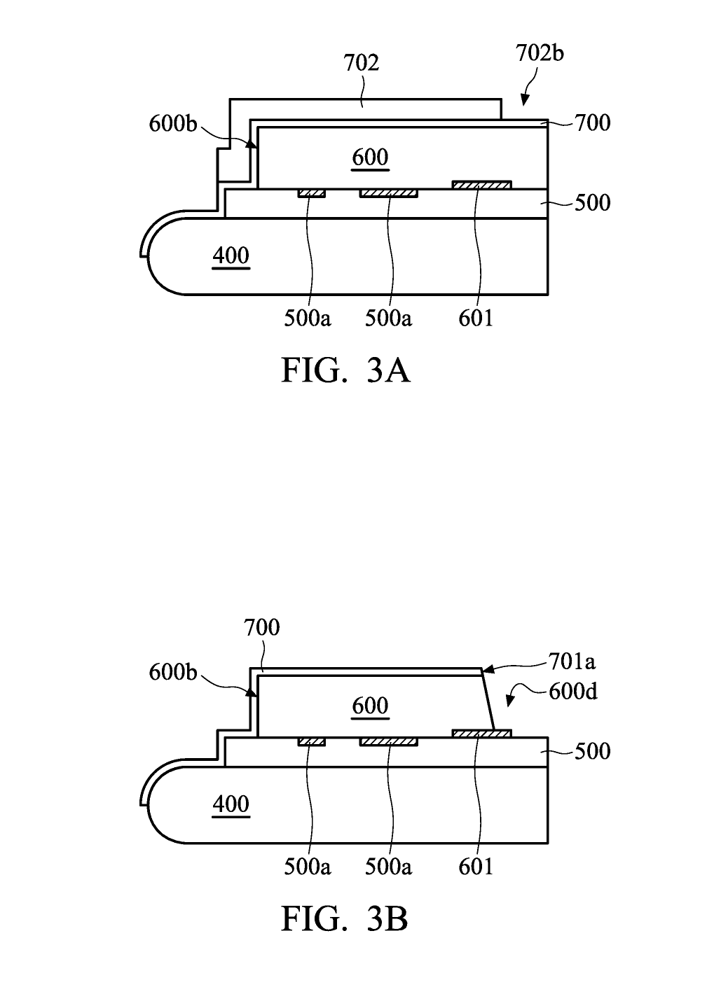

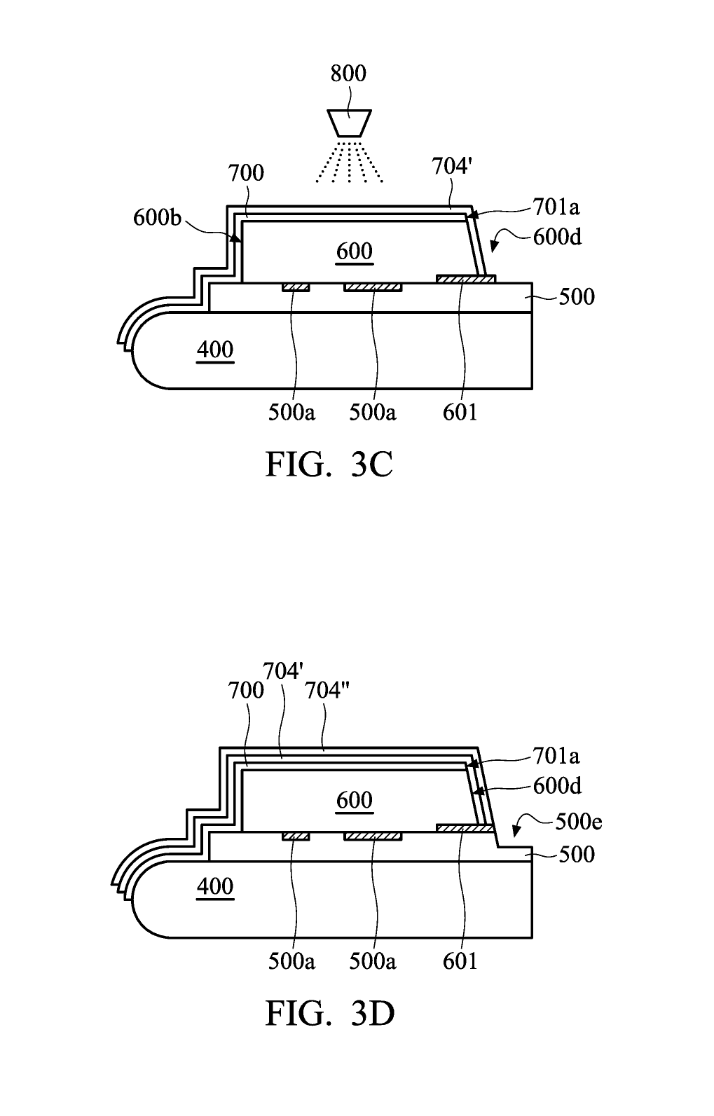

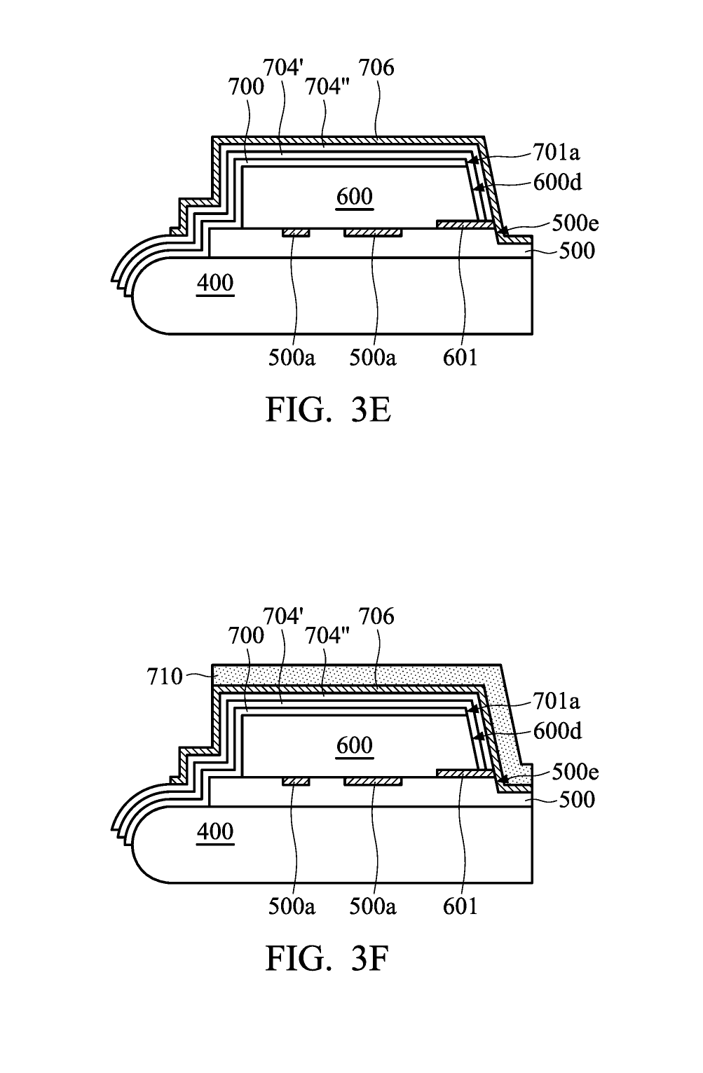

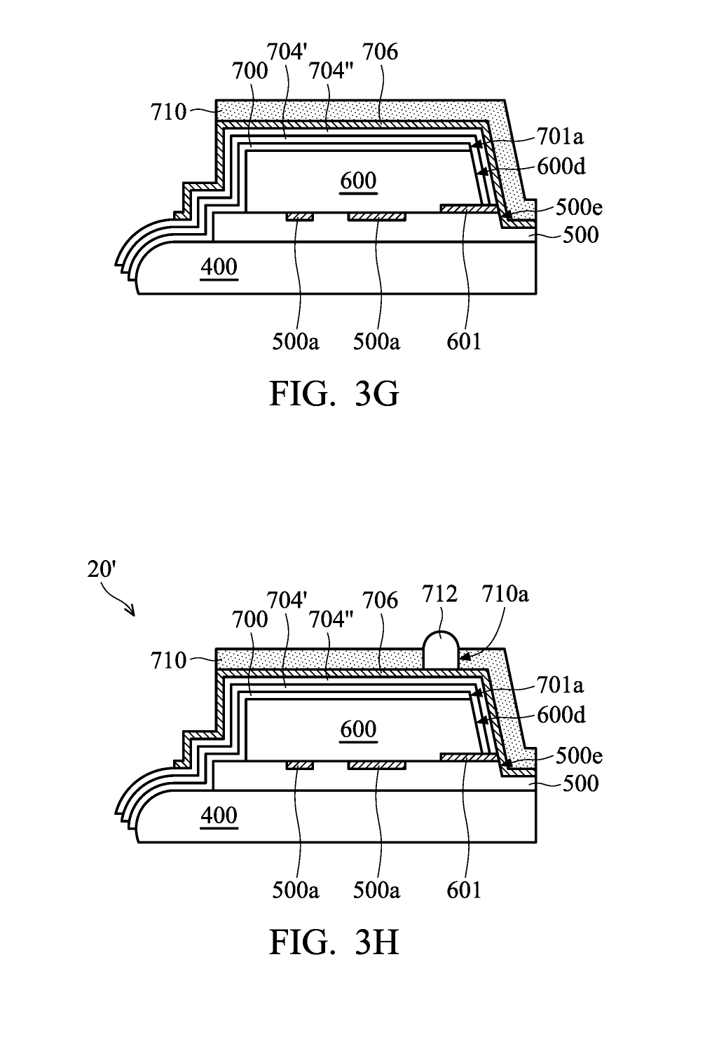

Refer to FIG. 3H, in which a cross-sectional view of an exemplary embodiment of a chip package 20′ according to the invention is illustrated. Elements in FIG. 3H that are the same as those in FIG. 2H are labeled with the same reference numbers as in FIG. 3H and are not described again for brevity. In the embodiment, the chip package 20′ is similar to the structure of the chip package 20 shown in FIG. 2H.

Unlike the chip package 20 shown in FIG. 2H, the second chip 600 of the chip package 20′ has at least one opening 600d passing through the second chip 600 and exposing an upper surface of the device substrate 500a and corresponding conductive pad 601 that is between the device substrate 500 and the second chip 600. Moreover, the opening 600d further extends into the device substrate 500 to form an opening 500e therein. Furthermore, the polymer protective layer 700 conformally covers the upper surface and sidewalls of the second chip 600, the exposed portion of the device substrate 500, and the edge of the carrier substrate 400 and has an opening 701a that substantially aligns to the opening 600d, so as to form a combined opening including openings 701a, 600d, and 500e.

In the embodiment, the chip package 20 further includes a dielectric layer 704′ that is disposed on the polymer protective layer 700 and extends on the sidewalls of the opening 701a of the polymer protective layer 700 and the opening 600d of the second chip 600. In one embodiment, the dielectric layer 704′ includes an organic polymer material without spacers therein. In these cases, the organic polymer material may be epoxy.

In the embodiment, the chip package 20 further includes a dielectric layer 704″ that is disposed on the dielectric layer 704′. In one embodiment, the dielectric layer 704″ includes the organic polymer material used in the dielectric layer 704′ and spacers. For example, the organic polymer material may be epoxy and the spacers may be silica particles. The epoxy enables the dielectric layer 704″ to have fluidity before curing, and the silica particles in the dielectric layer 704″ lowers the CTE of the dielectric layer 704″, so that the CTE of the dielectric layer 704″ is approximately the same as that of the second chip 600, thereby avoiding the warping deformation caused by thermal stress.

In the embodiment, the redistribution layer 706 disposed on the dielectric layer 704″ conformally extends on the sidewall and the bottom of the combined opening including openings 701a, 600d, and 500e, thereby electrically connecting the conductive pad 601 in the manner of a T-contact. The redistribution layer 706 is electrically isolated from the second chip 600 via the dielectric layers 704′ and 704″ between the redistribution layer 706 and the polymer protective layer 700.

In the embodiment, the passivation layer 710 is disposed on the redistribution layer 706 and covers the sidewall of the combined opening including openings 701a, 600d, and 500e. Moreover, the passivation layer 710 has at least one opening 710a that exposes a portion of the redistribution layer 706. The conductive structure 712 is disposed in the opening 710a of the passivation layer 710 and is electrically connected to the exposed portion of the redistribution layer 706.

Refer to FIGS. 3A to 3H, which illustrate cross-sectional views of an exemplary embodiment of various intermediate stages for forming a chip package 20′ according to the invention. Elements in FIGS. 3A to 3H that are the same as those in FIGS. 2A to 2H are labeled with the same reference numbers as in FIGS. 2A to 2H and are not described again for brevity. As shown in FIG. 3A, a structure shown in FIG. 2B is provided. A polymer protective layer 700 is formed to conformally cover the upper surface and the sidewall (i.e., the edge 600b) of the second chip 600, the upper surface and the sidewall of the exposed portion of the device substrate 500, and the edge of the carrier substrate 400. Thereafter, a masking pattern layer 702 is formed on the polymer protective layer 700, such as a photoresist pattern layer, above the device substrate 500 and the second chip 600. The masking pattern layer 702 has at least one opening 702b exposing a portion of the polymer protective layer 700 and corresponding to the conductive pad 601.

Refer to FIG. 3B, the polymer protective layer 700 and the underlying second chip 600 are successively patterned using the masking pattern layer 702 as an etch mask, so as to respectively form openings 701a and 600d in the polymer protective layer 700 and the underlying second chip 600, thereby exposing the conductive pad 601 and a portion of the device substrate 500. Next, the masking pattern layer 702 is removed.

Refer to FIG. 3C, a dielectric layer 704′ is conformally formed on the polymer protective layer 700. In the embodiment, the dielectric layer 704′ extends on the sidewalls of the opening 701a and the opening 600d and partially covers the conductive pad 601. In one embodiment, the dielectric layer 704′ includes an organic polymer material (such as epoxy) without spacers (such as silica particles) therein. In this case, the dielectric layer 704′ is formed by a spray coating process using a nozzle 800. The dielectric layer 704′ does not contain any spacer, so as to prevent the nozzle 800 from being blocked by the spacers in the spray coating process. Moreover, the dielectric layer 704′ made of epoxy can be uniformly formed on the polymer protective layer 700 in the spray coating process. In this way, the dielectric layer 704′ not only enhances the electrical isolation property of the second chip 600, but also enhances package miniaturization. In some embodiments, the dielectric layer 704′ can be formed with a thickness in a range of about 5 μm to 20 μm.

Refer to FIG. 3D, a dielectric layer 704″ is formed on the polymer dielectric layer 704′. In the embodiment, the dielectric layer 704″ also extends on the sidewalls of the opening 701a and the opening 600d and partially covers the conductive pad 601. In one embodiment, the dielectric layer 704″ includes the organic polymer material (such as epoxy) used in the dielectric layer 704′ and spacers (such as silica particles) in the organic polymer material. In some embodiments, deposition of the epoxy having silica particles therein makes sure the CTE of the formed dielectric layer 704″ is approximately the same as that of the second chip 600, and therefore the subsequently formed chip package can maintain good reliability under repetitive heating and cooling tests. In one embodiment, the dielectric layer 704″ that is made of the epoxy having silica particles therein is formed by a spin coating process. In this case, since the dielectric layer 704″ has fluidity before curing, part of the epoxy having silica particles gather at the bottom of the opening 600d. As a result, the dielectric layer 704″ at the sidewall of the opening 600d is affected by gravity and flows down to the bottom of the opening 600d, so that the thickness of the dielectric layer 704″ above the second chip 600 is greater than that of the dielectric layer 704″ on the sidewall of the opening 600d. In this case, the thickness of the dielectric layer 704″ above the second chip 600 may be in a range of 20 μm to 25 μm. In some embodiments, the dielectric layer 704″ is formed by another suitable deposition process, such as a printing process.

Next, a portion of the dielectric layer 704″ on the sidewall of the opening 600d and a portion of the device substrate 500 at the bottom of the opening 600d are removed by a cutting process to extend the opening 600d into the device substrate 500, so as to form an opening 500e in the device substrate and expose the sidewall of the conductive pad 601.

Refer to FIG. 3E, a redistribution layer 706 is conformally formed on the dielectric layer 704″. In the embodiment, the redistribution layer 706 on the dielectric layer 704″ conformally extends on the sidewall and the bottom of the combined opening including openings 701a, 600d, and 500e, thereby electrically connecting the conductive pad 601 in the manner of a T-contact. The redistribution layer 706 is electrically isolated from the second chip 600 via the dielectric layers 704′ and 704″ between the redistribution layer 706 and the polymer protective layer 700.

Refer to FIG. 3F, a passivation layer 710 is formed on the redistribution layer 706 and covers the sidewall and the bottom of the combined opening including openings 701a, 600d, and 500e.

Refer to FIG. 3G, a polishing process (e.g., a chemical mechanical polishing process) is performed on the carrier substrate 400 to thin the thickness of the carrier substrate 400.

Refer to FIG. 3H, the passivation layer 710 is patterned by lithography and etching processes to form at least one opening 710a that exposes a portion of the redistribution layer 706. In some embodiments, the passivation layer 710 includes a photoresist material. As a result, the opening 710a can be formed by a lithography process when the passivation layer 710 is formed. Thereafter, a conductive structure 712 is formed in the opening 710a of the passivation layer 710, so as to be electrically connected to the exposed portion of the redistribution layer 706. Thereafter, a dicing process may be performed along the scribe lines (not shown) to complete the fabrication of the chip package 20′.

According to the foregoing embodiments, since the polymer protective layer 700 covers the portion of the device substrate 500 exposed from the second chip 600, the exposed portion of the device substrate 500 can be prevented from being etched during the fabrication of the chip package 20 or 20′. As a result, since a recess is not formed in the device substrate 500 between the second chip 600 and the carrier substrate 400, disconnection of the subsequent redistribution layer 706 can be prevented when the redistribution layer 706 is formed.

Since the polymer protective layer 700 also covers the upper surface and the sidewall (i.e., the edge 600b) of the second chip 600, the polymer protective layer 700 and/or the dielectric layers 704′ and 704″ may serve as stress buffer layers to prevent the edge of the second chip 600 from cracking when the polishing process (e.g., a thinning process) is performed on the carrier substrate 400. Moreover, the polymer protective layer 700 and/or the dielectric layers 704′ and 704″ may also prevent moisture from entering into the device substrate 500 and the second chip 600, thereby increasing the reliability of the chip package 20 or 20′.

Since the dielectric layer 704′ with good uniformity can enhance the electrical isolation between the second chip 600 and the redistribution layer 706, there is no need to further increase the thickness of the dielectric layer 704″. Moreover, the dielectric layer 704″ prevents the cracking of the chip package 20′ due to repetitive heating and cooling tests to cause the risk of disconnection of the redistribution layer 706, and therefore the yield and the reliability of the chip package 20′ can be increased.

While the invention has been disclosed in terms of the preferred embodiments, it is not limited. The various embodiments may be modified and combined by those skilled in the art without departing from the concept and scope of the invention.

What is claimed is:

1. A chip package, comprising:
a first chip comprising:
a carrier substrate; and
a device substrate disposed on the carrier substrate;
a second chip mounted on the device substrate, wherein a portion of the device substrate extends outward from an edge of the second chip, so as to be exposed from the second chip;
a conductive pad between the device substrate and the second chip;
a polymer protective layer conformally covering the edge of the second chip, an edge of the exposed portion of the device substrate, and an edge of the carrier substrate; and
a redistribution layer disposed on the polymer protective layer and extending into a first opening that passes through the polymer protective layer and the second chip and exposes the conductive pad, so as to be electrically connected to the conductive pad.

2. The chip package as claimed in claim 1, further comprising:
a first dielectric layer disposed between the redistribution layer and the polymer protective layer.

3. The chip package as claimed in claim 2, further comprising:
a second dielectric layer disposed between the redistribution layer and the first dielectric layer, wherein the first dielectric layer comprises an organic polymer material and the second dielectric layer comprises the organic polymer material and spacers therein.

4. The chip package as claimed in claim 3, wherein the organic polymer material is epoxy and the spacers are silica particles.

5. The chip package as claimed in claim 1, further comprising:
a passivation layer disposed on the redistribution layer and partially filling the first opening, so that a cavity is formed between the conductive pad and the passivation layer, wherein the passivation layer has a second opening exposing the redistribution layer; and
a conductive structure disposed in the second opening and electrically connected to the redistribution layer.

6. The chip package as claimed in claim 5, wherein the conductive structure comprises a metal bump.

7. The chip package as claimed in claim 1, wherein the polymer protective layer comprises a photo-sensitive material.

8. The chip package as claimed in claim 1, wherein the device substrate comprises a micro-electromechanical systems device therein.

9. The chip package as claimed in claim 1, wherein the second chip is an application-specific integrated circuit chip.

10. A method for forming a chip package, comprising:
providing a first chip comprising:
a carrier substrate; and
a device substrate disposed on the carrier substrate;
mounting a second chip on the device substrate, wherein a portion of the device substrate extends outward from an edge of the second chip, so as to be exposed from the second chip;
forming a polymer protective layer to conformally cover the edge of the second chip, an edge of the exposed portion of the device substrate, and an edge of the carrier substrate;
forming a first opening passing through the polymer protective layer and the second chip to expose a conductive pad between the device substrate and the second chip; and
forming a redistribution layer on the polymer protective layer and extending into the first opening, so as to be electrically connected to the conductive pad.

11. The method as claimed in claim 10, further comprising:
forming a first dielectric layer between the redistribution layer and the polymer protective layer.

12. The method as claimed in claim 11, further comprising:
forming a second dielectric layer between the redistribution layer and the first dielectric layer, wherein the first dielectric layer comprises an organic polymer material and the second dielectric layer comprises the organic polymer material and spacers therein.

13. The method as claimed in claim 12, wherein the organic polymer material is epoxy and the spacers are silica particles.

14. The method as claimed in claim 10, wherein the polymer protective layer comprises a photo-sensitive material.

15. The method as claimed in claim 10, further comprising:
forming a passivation layer on the redistribution layer and partially filling the first opening, so that a cavity is formed between the conductive pad and the passivation layer;
forming a second opening in the passivation layer to expose the redistribution layer; and
forming a conductive structure in the second opening, so as to be electrically connected to the redistribution layer.

16. The method as claimed in claim 15, wherein the conductive structure comprises a metal bump.

17. The method as claimed in claim 15, further comprising performing a polishing process on the carrier substrate prior to formation of the conductive structure.

18. The method as claimed in claim 10, wherein the device substrate comprises a micro-electromechanical systems device therein.

19. The method as claimed in claim 10, wherein the second chip is an application-specific integrated circuit chip.

20. The method as claimed in claim 10, further comprising performing a polishing process on the second chip prior to formation of the polymer protective layer.
